(19) United States
(12) Patent Application Publication
(10) Pub. No.: US 2018/0324368 A1
(43) Pub. Date: Nov. 8, 2018

(54) OPTICAL SYSTEM FOR THERMAL IMAGER

(71) Applicant: IRLYNX, Montbonnot-saint-martin (FR)

(72) Inventors: Sandrine OEUVRARD, Grenoble (FR); Christophe MARTINSONS, Le Touvet (FR); Benoit TAEYMANS, Grenoble (FR)

(21) Appl. No.: 15/770,452

(22) PCT Filed: Oct. 12, 2016
(86) PCT No.: PCT/FR2016/052631

§ 371 Date: Apr. 23, 2018

(30) Foreign Application Priority Data
Oct. 22, 2015 (FR) FR15 60109

(51) Int. Cl. H04N 5/33; G02B 5/10; G02B 13/14; G02B 17/00; G03B 17/17

(52) U.S. Cl. CPC H04N 5/33; G02B 5/10; G03B 17/17; G02B 17/002; G02B 13/14

(57) ABSTRACT

The invention relates to an optical system with mirrors for an image sensor, comprising two symmetrical concave mirrors (20a, 20b) arranged in the same plane and having parallel optical axes (Oa, Ob); and an image sensor array (24) arranged in front of the mirrors and having two opposing edges which are respectively substantially adjacent to the optical axes of the two mirrors. The image sensor can be attached to an opaque mask (28) comprising, on the periphery of the image sensor, an entrance pupil (26) in front of each mirror (20), contained in the surface of the mirror extending beyond the image sensor.

### FIELD

The invention relates to thermal imagers and in particular to an optical system adapted to such imagers.

### BACKGROUND

A thermal imager may include an image sensor array sensitive to a wavelength greater than 2 μm, provided with an optical system for focusing an image on the sensor. The optical system may have a configuration similar to the lenses for visible radiation, except that the lenses use a material that is transparent to thermal radiation. Such materials are expensive and generally have a low transmission rate.

FIG. 1 is a schematic sectional view of an exemplary low cost optical system adapted to thermal radiation, as described in patent application WO 2002-063872. The optical system includes mirrors arranged in a Gregorian telescope configuration. Rays from the observed scene reach a concave main mirror 10 (usually a paraboloid) and are reflected to a secondary mirror 12 (generally a concave ellipsoid). The mirror 12 reflects the rays to an image sensor 14 located behind a central opening of the main mirror 10.

The secondary mirror 12 is located between the scene and the main mirror 10. This mirror is attached to a support 16 that filters the incoming radiation. The support 16 has a high transparency to the thermal rays to not impair the sensitivity of the imager.

Since the optical system has a telescope configuration, it has a narrow field of view and is unsuitable for indoor scenes.

### SUMMARY

An optical system is generally provided for a thermal imager, comprising two symmetrical concave mirrors located in a same plane and having parallel optical axes; and an image sensor array located in front of the mirrors and having two opposite edges respectively substantially adjacent to the optical axes of the two mirrors.

The image sensor may be attached to an opaque mask comprising, at the periphery of the image sensor, an entrance pupil in front of each mirror, contained in a surface of the mirror extending beyond the image sensor.

Each pupil and the corresponding mirror may be configured such that a ray parallel to the optical axis reaching the mirror through the pupil is reflected towards a nearest edge of the image sensor; and a ray at a limit angle passing through the pupil and reaching an edge of the mirror under the image sensor is reflected towards an axis of symmetry of the image sensor.

The pupils may be adjacent respectively to the optical axes.

The mirrors may substantially have a same form factor as the optical sensor, and have an ellipsoidal surface.

The optical system may further comprise four concave mirrors with parallel optical axes, configured in four adjacent quadrants, four corners of the image sensor being substantially adjacent respectively to the four optical axes; and four entrance pupils respectively located at the four corners of the image sensor.

### BRIEF DESCRIPTION OF DRAWINGS

Other advantages and features will become more clearly apparent from the following description of particular embodiments of the invention provided for exemplary purposes only and represented in the appended drawings, in which:

FIG. 1, previously described, is a schematic sectional view of a conventional optical system with mirrors for a thermal imager;

FIG. 2 is a schematic sectional view of an embodiment of a wide field of view optical system using mirrors;

FIG. 3 is a schematic front view of an embodiment of a wide field of view optical system using mirrors;

FIG. 4 is a perspective view of the optical system of FIG. 3; and

FIGS. 5A and 5B show an example of an image projected by the optical system of FIG. 3 on an image sensor array and a transformation of the image in view of its processing.

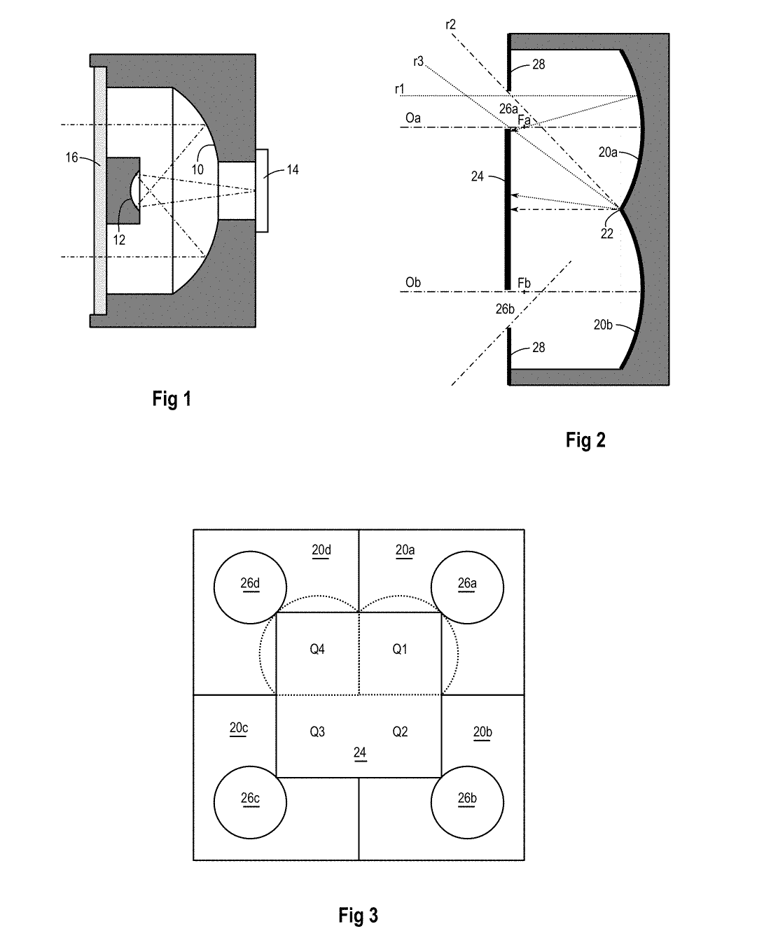

### DESCRIPTION OF EMBODIMENTS

In FIG. 2, an embodiment of an optical system with a wide field of view is formed by a symmetrical assembly of two optical subsystems using mirrors. The mirrors 20a and 20b of the two subsystems are concave and have parallel optical axes Oa and Ob oriented towards the scene to be viewed. The two mirrors are in the same plane and may be adjacent along a common ridge 22 located in a plane of symmetry of the optical system.

An image sensor array 24 is located in a plane parallel to that of the mirrors, between the mirrors and the scene, and offset with respect to the optical axes. The sensor 24 overlaps the ridge 22 and preferably reaches the two optical axes, as shown. The position of the sensor plane relative to the focal plane of the mirrors determines the focus distance. The focal plane passes through the optical foci Fa and Fb of the mirrors. For distant objects, the focal plane and the plane of the sensor would be merged. To obtain a substantially sharp image with a fixed focus optical system for objects located a few meters away, as in a room to be monitored, the plane of the sensor may be offset toward the scene relative to the focal plane.

With this configuration, as shown for the mirror 20a, an incoming ray directed along the optical axis Oa brushes past the nearest edge of the image sensor 24, reaches the center of the mirror, and is reflected to the edge of the sensor in alignment with the optical axis. An incoming ray r1, parallel to the optical axis Oa and offset from the edge of the sensor 24, exits through the focus Fa and hits the sensor near its edge.

For sake of clarity of the disclosure, it is assumed that the edges of the physical image sensor coincide with the edges of the sensitive area of the sensor. In practice, the sensitive area may be set back from the edges of the sensor. The principles described here actually apply to the sensitive area of the sensor.

An oblique ray r2 that hits the common ridge 22 is reflected at an angle that depends on the angle of incidence of the ray on the mirror 20a. The ray r2 as shown defines with the optical axis Oa the field of view of the optical subsystem, i.e. the ray r2 has the largest angle among the rays reflected toward the sensor by the mirror 20a.

In this configuration, it is desired, as shown, that the ray r2 be reflected towards an axis of symmetry of the sensor 24. Then, any ray hitting the ridge 22 with an angle smaller than that of the ray r2, like a ray r3, is reflected toward the same, upper half of the sensor 24. This constraint may be satisfied, for example, by an ellipsoidal mirror adapted to the dimensions of the optical system.

A ray that reaches the ridge 22 with an angle greater than that of the limit ray r2 would be reflected towards the second, lower half of the sensor 24. This is not desirable, because the second half of the sensor is used symmetrically by the second optical subsystem associated with the mirror 20b. To block such rays, an off-axis entrance pupil 26a may be provided in the form of a suitably sized orifice formed in a mask 28 that is opaque to the used radiation. A symmetrical pupil 26b is then provided for the second optical subsystem.

The mask 28 may be placed in a large latitude along the optical axes, the size and the position of the pupil 26a being defined by the generating lines formed by the optical axis Oa and the limit ray r2. Preferably, as shown, the mask 28 is placed in the plane of the image sensor 24, so that it can directly serve as a support for attaching the sensor.

The pupil 26a does not block oblique rays that cross the ridge 22 and reach the second mirror 20b. Such rays do not affect the imager, because they are reflected by the mirror 20b outside the sensor 24.

By thus associating two off-axis symmetrical optical subsystems, the field of view of the imager can be doubled in the plane of the optical axes. To double the field of view in all directions, four off-axis optical subsystems may be assembled together as described below.

FIG. 3 is a schematic front view of an embodiment of an optical system having a wide field of view in all directions. Four concave mirrors 20a to 20d with parallel optical axes are configured in four adjacent quadrants Q1 to Q4. The image sensor 24 may be centered above the four quadrants and its four corners are preferably adjacent respectively to the four optical axes of the mirrors. The mirrors may have the same form factor as the sensor and be adjacent along ridges contained in two orthogonal planes of symmetry of the optical system. The mirrors and the sensor are square here, but they could be rectangular.

Four entrance pupils 26a to 26d are respectively associated with the four mirrors 20a to 20d. The pupils may be adjacent respectively to the four optical axes, themselves adjacent to the four corners of the sensor 24, in this embodiment. The pupils 26 are furthermore situated on diagonals of the image sensor—FIG. 2 can thus be considered as a sectional view along a diagonal of the system of FIG. 3.

The pupils 26 have been shown in a circular form. They could be rectangular with the same form factor as the image sensor. Circular pupils, however, act as diaphragms—the diameter of the pupils, which depends on the position of the pupils along the optical axes, influences the depth of field of the optical system and the amount of radiation transmitted to the sensor. Preferably, as shown, each pupil is contained in the mirror surface area extending beyond the image sensor. With this configuration all the rays parallel to the optical axes and passing through the pupils reach the mirrors.

Dotted areas correspond to images projected by the pupils 26a and 26d on the plane of the image sensor 24. These images are substantially circles that are truncated at the axes of symmetry delimiting the quadrants of the image sensor. The diameter of the truncated circles is in principle equal to half a diagonal of the sensor, so that a diagonal limit ray (r2 in FIG. 2) reaching the common point between the four mirrors is reflected towards the center of the image sensor.

The quality of the mirror surface at the adjacent ridges defines the quality of the truncated edges of circle images. In practice, it is difficult to make the ridges with a constant quality. Thus, the images formed in the four quadrants may have blurry edges along the symmetry axes of the sensor. This is not an issue, as will be disclosed later.

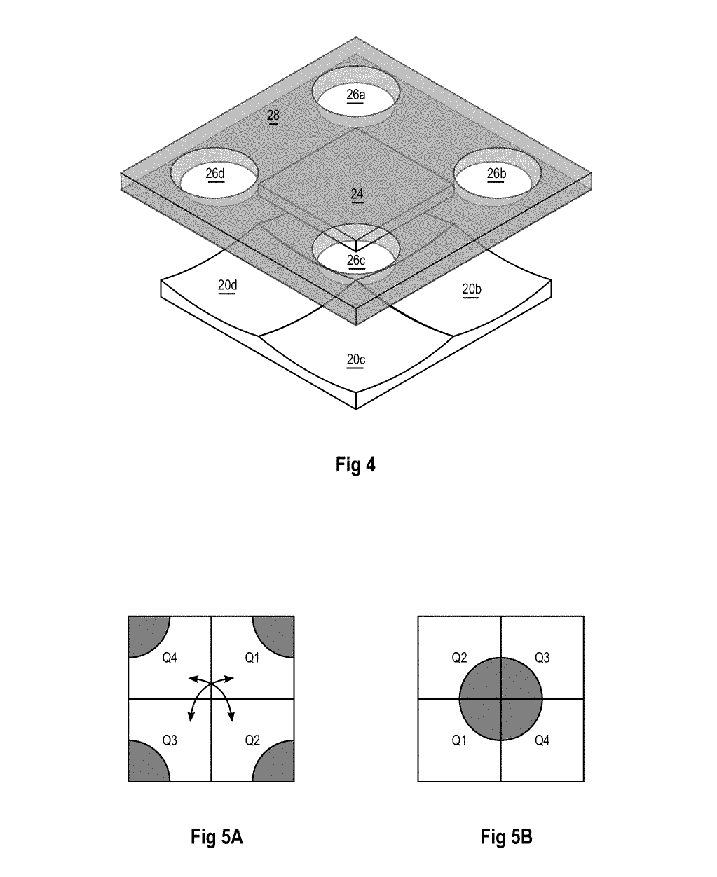

FIG. 4 is a perspective view of the four-quadrant optical system of FIG. 3. This view shows in the foreground the mask 28, not illustrated in the view of FIG. 3. Some elements of the sensor are shown by transparency through the mask 28. Since the mask 28 may have a certain thickness, serving to ensure a stable support of the image sensor 24, the entrance pupils 26 are preferably frustoconical, according to cones defined by the generating lines formed by the optical axes and the corresponding limit rays r2 (FIG. 2). If they are not exactly frustoconical, the pupils may be formed by several cylindrical portions of different radii approaching the frustoconical shape.

FIGS. 5A and 5B show an example of an image projected by the optical system of FIG. 3 or 4 on the image sensor 24, and a transformation of the image in view of processing it. The object viewed is a circle placed in the center of the field of view of the imager.

Recall, as illustrated in FIG. 2 for a two-mirror optical system, that the rays parallel to the optical axes, originating from the center of the viewed scene, are reflected towards an edge of the sensor, while the rays coming from an edge of the scene are reflected towards the center of the sensor. Thus the center of the scene is reflected towards the edges of the sensor, and the edges of the scene are reflected towards the center of the sensor. The useful final image is thus obtained by exchanging the half-images produced by the two halves of the image sensor.

In FIG. 5A, in a four-mirror system of the type of FIGS. 3 and 4, the center of the scene is reflected towards the corners of the sensor, and the corners of the scene are reflected towards the center of the sensor. Thus, a circle in the center of the field of view is perceived by the image sensor as respective quarter circles at the four corners of the sensor, as shown.

In FIG. 5B, to reconstruct a usable image of the circle, the four quadrants of the image supplied by the sensor are diagonally exchanged, as shown by arrows in FIG. 5A. Thus, quadrant Q1 is exchanged with quadrant Q3, and quadrant Q2 is exchanged with quadrant Q4.

Thus, the edges of the final image receive the parts initially located at the symmetry axes of the sensor, i.e. the parts formed by the rays reflected by the ridges between adjacent mirrors, which can be deteriorated by the surface quality of the ridges. The imperfections due to the ridges are therefore found at the edges of the final image, edges that do not convey any useful information, in practice.

The center of the final image has a blind zone corresponding to the part hidden by the sensor. This blind zone is however defined between rays penetrating parallel to the optical axes, whereby the blind zone corresponds to a projected zone of the size of the sensor on the object in the center of the field of view. If the object is sufficiently far, the projected zone may be much smaller than a pixel of the sensor, and thus be totally imperceptible.

By way of example, an imager was realized having a field of view of about 80° with ellipsoidal mirrors having a conical constant of 0.199 and a curvature radius of 12.067 mm. The mirrors and the image sensor array had the same diagonal of about 13.6 mm. The image sensor was placed in the optical focal plane of the mirrors at about 5.7 mm from the ellipsoid hollows. The pupils had a diameter of 3.8 mm. With these dimensions, it was possible to obtain an image of satisfactory sharpness from 0.2 to 20 meters.

Many variations and modifications of the embodiments described herein will be apparent to the skilled person. For example, the mirrors do not need to be in contact with each other. There may be a gap between the edges of two adjacent mirrors, which results in a central band without information on the image sensor. This band, corresponding to the edge of the image, generally does not convey useful information.

Instead of providing a single image sensor covering all four quadrants, an independent image sensor may be provided for each quadrant—this solution would be more expensive than providing a single sensor.

Preferably the edges of the sensor, or more precisely the edges of the sensitive area of the sensor are adjacent to the optical axes. Of course, this configuration may be respected within the limits of a margin of tolerance. If the edges are set back from the optical axes, information may be lost in a central band of the field of view. If the edges protrude beyond the optical axes, the protruding parts of the sensor are not illuminated and cause a black band in the center of the reconstructed image. This last case is preferable to the first, because there is no loss of information—the black band can be removed by post-processing the image.

1. An optical system for a thermal imager, comprising:
two symmetrical concave mirrors located in a same plane and having parallel optical axes;
an image sensor array located in front of the mirrors and having two opposite edges respectively substantially adjacent to the optical axes of the two mirrors; and
an opaque mask on which the image sensor is attached, the mask comprising, at the periphery of the image sensor, an entrance pupil in front of each mirror, contained in a surface of the mirror extending beyond the image sensor.

2. The optical system according to claim 1, wherein each pupil and the corresponding mirror are configured such that:
a ray parallel to the optical axis reaching the mirror through the pupil is reflected towards a nearest edge of the image sensor; and
a ray at a limit angle passing through the pupil and reaching an edge of the mirror under the image sensor is reflected towards an axis of symmetry of the image sensor.

3. The optical system according to claim 2, wherein the pupils are adjacent respectively to the optical axes.

4. The optical system according to claim 2, wherein the mirrors have substantially a same form factor as the optical sensor, and have an ellipsoidal surface.

5. The optical system according to claim 1, comprising:
four concave mirrors with parallel optical axes, configured in four adjacent quadrants, four corners of the image sensor being substantially adjacent respectively to the four optical axes; and
four entrance pupils respectively located at the four corners of the image sensor.
